(19) United States
(12) Patent Application Publication
(10) Pub. No.: US 2008/0124852 A1
(43) Pub. Date: May 29, 2008

(54) Method of forming T- or gamma-shaped electrode

(75) Inventors: Ho Kyun Ahn, Daejeon (KR); Jong Won Lim, Daejeon (KR); Jae Kyoung Mun, Daejeon (KR); Woo Jin Chang, Daejeon (KR); Hong Gu Ji, Daejeon (KR); Hae Cheon Kim, Daejeon (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Electronics and Telecommunications Research Institute

(21) Appl. No.: 11/605,508

(22) Filed: Nov. 28, 2006

(51) Int. Cl. H01L 21/338

(52) U.S. Cl. 438/182

(57) ABSTRACT

A method of forming a fine T- or gamma-shaped gate electrode is provided, which is performed by a lithography process using a multi-layered photoresist layer having various sensitivities, deposition of an insulating layer, and an etching process. The method includes: a first step of depositing a first insulating layer on a semiconductor substrate; a second step of coating at least two photoresist layers with different sensitivities from each other on the first insulating layer, and patterning the photoresist layers to have openings which are different in size; a third step of etching the first insulating layer using the photoresist layers as etch masks to form a step hole in which a part contacting the substrate is narrower than an upper part thereof, and removing the photoresist layers; a fourth step of forming a photoresist layer on the first insulating layer, and forming an opening in the photoresist layer to have a T- or gamma-shaped gate head pattern; a fifth step of performing a gate recess process with respect to the gate pattern; and a sixth step of depositing a gate metal on the gate pattern, and removing the photoresist layers.

### CROSS-REFERENCE TO RELATED APPLICATION

This application claims priority to and the benefit of Korean Patent Application No. 2005-114565, filed Nov. 29, 2006, the disclosure of which is incorporated herein by reference in its entirety.

### BACKGROUND

1. Field of the Present Invention

The present invention relates to a method of forming a gate electrode, and more particularly, to a method of forming a T- or gamma-shaped gate electrode.

2. Discussion of Related Art

Fine T- or gamma-shaped electrodes are gate electrodes widely employed in manufacturing a transistor that is used in the field using a high-frequency. As semiconductor devices are highly integrated, there are various researches on a method of forming an electrode which can reduce the length of a gate, has excellent high frequency characteristics, and does not deteriorate gain or noise characteristics.

A conventional process of forming such a T- or gamma-shaped electrode will now be descried with reference to FIGS. 1A to 1E.

First, an active layer 20 and a capping layer 30 are sequentially formed on a compound semiconductor substrate such as a semi-insulating GaAs substrate, or another semiconductor substrate 10 (in FIG. 1A). A region in which an ohmic metal layer 40 will be formed is defined by a photoresist pattern, and an ohmic metal is deposited, thereby completing the ohmic metal layer 40 through a rapid thermal annealing process, etc. (in FIG. 1B). In the case of manufacturing a device such as a high electron mobility transistor (HEMT) using a compound semiconductor or a metal semiconductor field effect transistor (MESFET), the ohmic metal layer 40 may be a metal layer formed by sequentially depositing AuGe, Ni and Au to a predetermined thickness.

Photoresist layers 50, 60 and 70 are formed on the substrate having the ohmic metal layer 40, and a T-shaped gate pattern is formed by a photo lithography or electron beam lithography process (in FIG. 1C).

A gate recess region 80 in which a gate metal will be deposited is formed by performing a gate recess process for etching the semiconductor substrate 10 exposed by the T-shaped gate pattern (in FIG. 1D). The gate recess process, which is the most critical step in the manufacture of a device such as an HEMT using a compound semiconductor or a MESFET, is generally performed while measuring current, and may be performed in a single or several steps. For example, the gate recess process may be performed through a wet process, a dry process, or a combination of the wet and dry processes. For instance, the gate recess process may be performed using a gas such as BCl₃ or SF₆ in an apparatus for dry etching such as an electron cyclotron resonance (ECR) or inductive coupled plasma (ICP), or using various wet etching solutions such as a phosphoric acid-based solution in which H₃PO₄H₂O₂ and H₂O are mixed at a predetermined ratio.

Then, a gate metal 90 is deposited on the gate electrode pattern, and the photoresist layer is removed by a lift-off process, thereby completing a T-shaped gate electrode 90 (in FIG. 1E). Here, in the case of manufacturing a device such as an HEMT using a compound semiconductor or a MESFET, the gate electrode may be formed by sequentially depositing metal layers such as Ti, Pt and Au to a predetermined thickness.

However, according to the conventional method of forming a gate electrode, the length of a gate foot is determined by a resolution of a lithography process, and the height thereof is determined by the thickness of the photoresist layer. Accordingly, in consideration of the size of an opening pattern and the thickness of the photoresist layer, it is difficult to control the height of the gate foot with respect to the fine gate pattern, and thus there may be an increase in a parasitic component. Particularly, there is an additional increase in such a parasitic component when the gate head becomes wider.

For this reason, through the conventional method, it is difficult to stably manufacture a high-performance device having a T- or gamma-shaped electrode with a fine gate length.

On the other hand, in Korean Patent No. 10-0400718, a method of forming an ultra-fine gate is disclosed by the inventor in order to overcome this problem; which comprises the steps of: forming a step hole using double insulating layers having different etch rates from each other; forming a T-shaped gate in the hole to improve step coverage; and adjusting the length of a gate foot by depositing and etching back a third insulating layer. However, the invention also has a shortcoming in that it uses a multi-layered insulating layer with different etch rates.

### SUMMARY OF THE PRESENT INVENTION

The present invention is directed to a method of forming a gate electrode, which improves step coverage by a lithography process using a multi-layered photoresist layer with different sensitivities, deposition of an insulating layer, and an etching process, easily adjusts the height of a gate foot, and increases the cross-sectional area of the gate.

One aspect of the present invention provides a method of forming a T- or gamma-shaped gate electrode, comprising: a first step of depositing a first insulating layer on a semiconductor substrate; a second step of coating at least two photoresist layers with different sensitivities from each other on the first insulating layer, and patterning the photoresist layers to have openings which are different in size; a third step of etching the first insulating layer using the photoresist layers as etch masks to form a step hole in which a part contacting the substrate is narrower than an upper part thereof, and removing the photoresist layers; a fourth step of forming a photoresist layer on the first insulating layer, and forming an opening in the photoresist layer to have a T- or gamma-shaped gate head pattern; a fifth step of performing a gate recess process with respect to the gate pattern; and a sixth step of depositing a gate metal on the gate pattern, and removing the photoresist layers.

Here, the height of a gate foot may be adjusted by adjusting the thickness of the first insulating layer.

The first insulating layer may comprise at least one layer.

The photoresist layer coated in the second step may comprise at least two layers. The first photoresist layer contacting the first insulating layer may be formed of polymethyl methacrylate (PMMA) or ZEP, and the second photoresist layer contacting the first photoresist layer may be formed of methyl methacrylate-co-methacrylic acid polymer (MMA-MAA) or polymethylglutarimide (PMGI).

The openings of the first and second photoresist layers may have a size ratio of 1:1.2 to 1:3. The width of the lower step hole may be equal to that of the opening of the first photoresist layer, and the width of the upper step hole may be equal to that of the opening of the second photoresist layer.

The photoresist layer coated in the second step may comprise first and second photoresist layers. The first photoresist layer contacting the first insulating layer may be formed of MMA-MAA or PMGI, and the second photoresist layer contacting the first photoresist layer may be formed of PMMA or ZEP.

The openings of the first and second photoresist layers may have a size ratio of 1:0.3 to 1:0.8. The width of the lower part of the step hole may be equal to that of the opening of the second photoresist layer, and the width of the upper part of the step hole may be equal to that of the opening of the first photoresist layer.

The step of etching the first insulating layer in the third step may be performed by a dry etching process, for example, reactive ion etching (RIE), magnetically enhanced reactive ion etching (MERIE), or induced coupled plasma (ICP).

The dry etching process may be performed using a gas or a gaseous mixture selected from the group consisting of CF₄, a mixture of CF₄ and CHF₃, a mixture of CF₄ and O₂, and C₂H₆.

The photoresist layer in the fourth step may comprise at least one layer, and have a bar-, T- or gamma-shaped gate head pattern.

The photoresist layer in the fourth step may comprise at least two layers. The lower photoresist layer may have an opening smaller than that of the upper photoresist layer, thereby forming a T- or gamma-shaped gate head pattern whose upper part is wider than the lower part.

The gate recess process of the fifth step may be sequentially performed by a first wet etching process, a dry etching process, and a second wet etching process.

The dry etching process may be performed by electron cyclotron resonance (ECR), or ICP.

The dry etching process may use BCl₃ or SF₆.

The first and second wet etching processes may use a phosphoric acid-based solution in which H₃PO₄H₂O₂ and H₂O are mixed at an appropriate ratio.

The gate metal of the sixth step may be formed by sequentially stacking Ti, Pt and Au.

The removal of the photoresist layer in the sixth step may be performed by a lift-off process.

Also, after the third step, the method may further comprise the steps of depositing a second insulating layer on the first insulating layer, and etching back the second insulating layer to expose a part of the semiconductor substrate and remain the second insulating layer on a wall of the step hole.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A to 1E are cross-sectional views illustrating a conventional method of forming a gate electrode;

FIGS. 2A to 2K are cross-sectional views illustrating a method of forming a gate electrode according to an exemplary embodiment of the present invention; and

FIG. 3 is a cross-sectional view illustrating a method of forming a gate electrode according to another exemplary embodiment of the present invention.

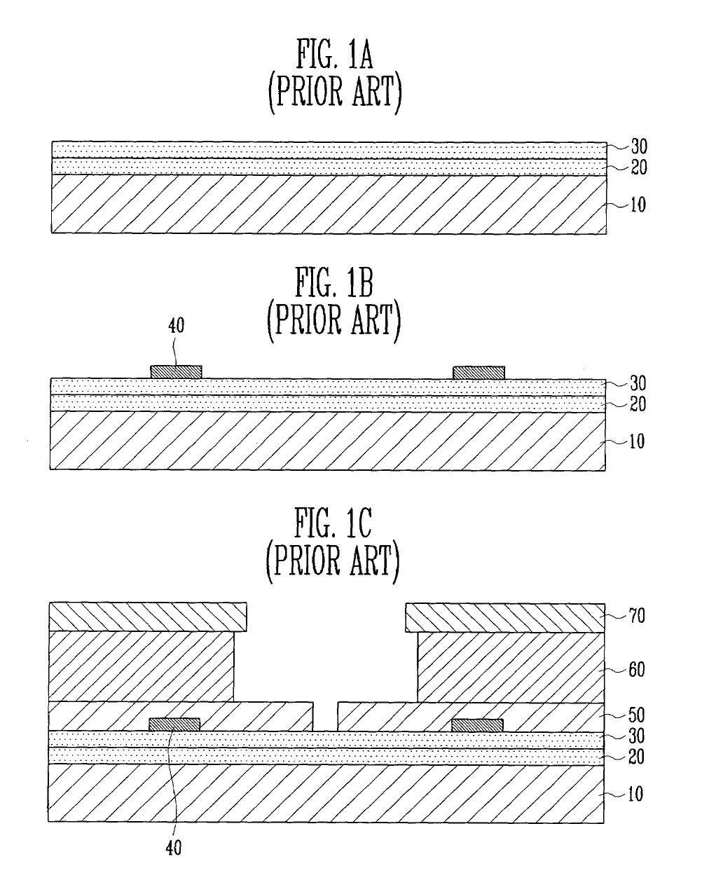

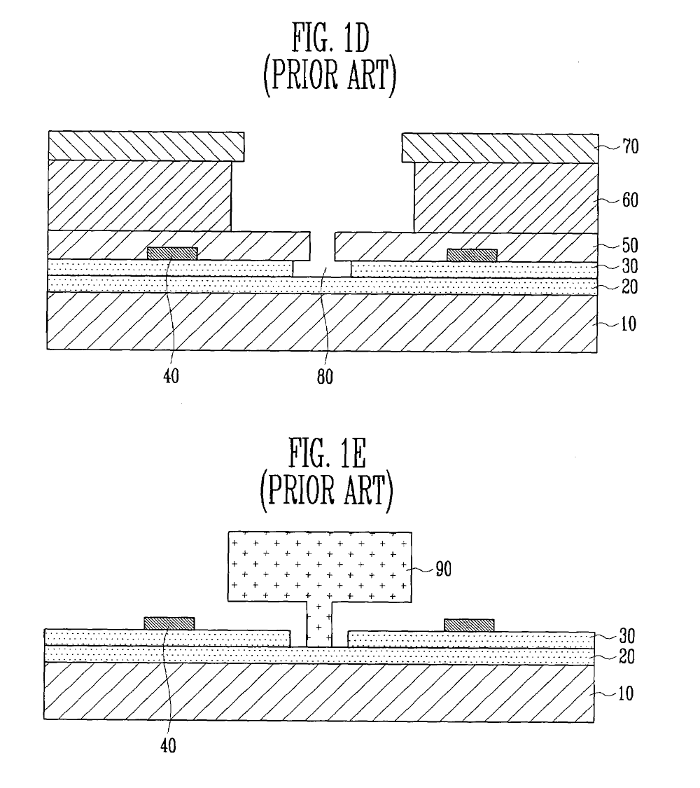

### DETAILED DESCRIPTION OF EXEMPLARY EMBODIMENTS

The present invention will now be described in more detail hereinafter with reference to the accompanying drawings, in which exemplary embodiments of the present invention are shown. The present invention may be embodied in various forms and not be limited to the exemplary embodiments described herein.

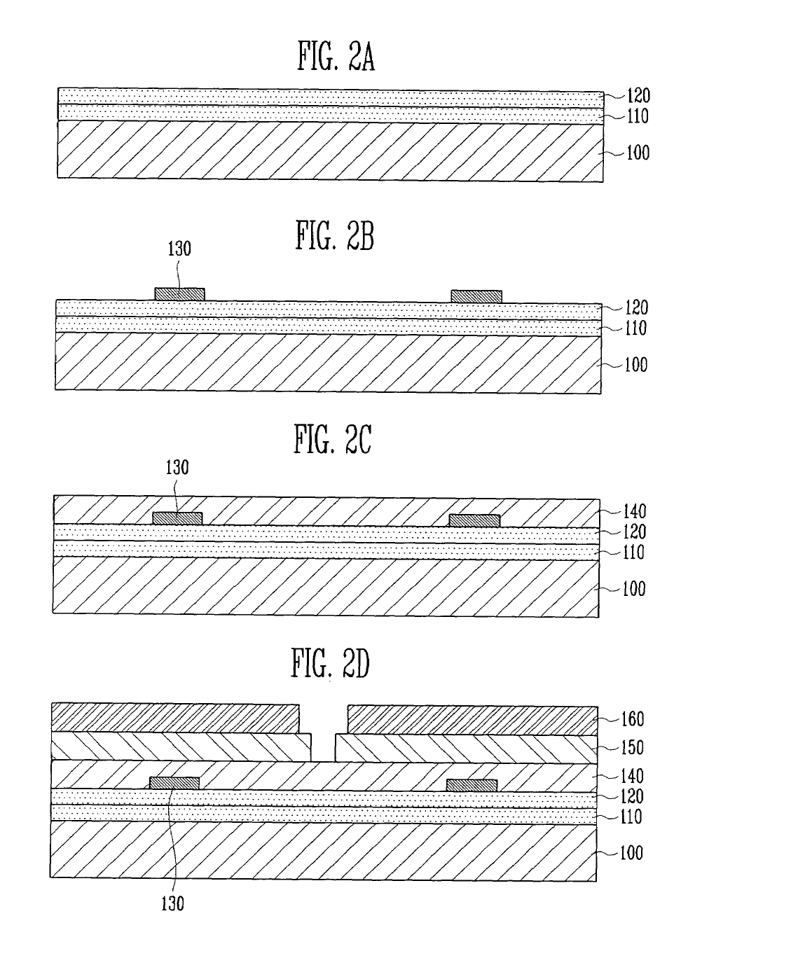

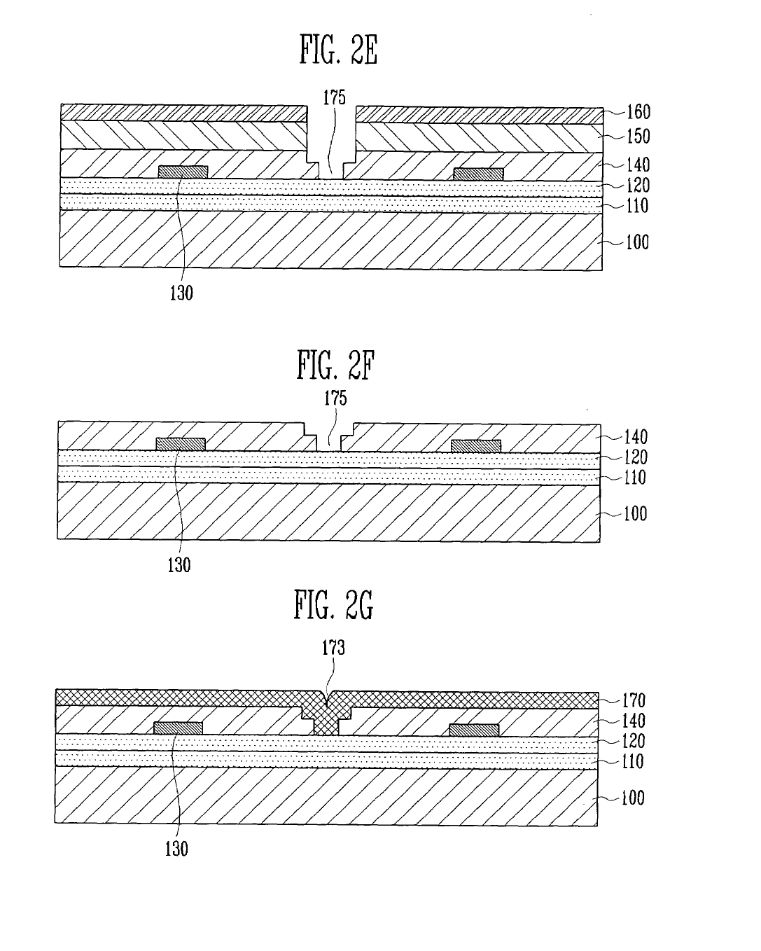

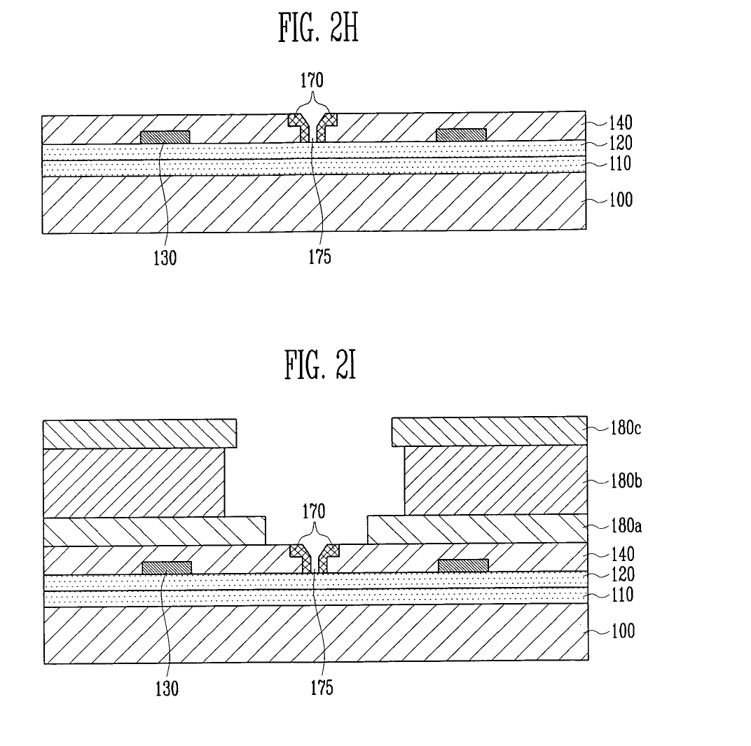

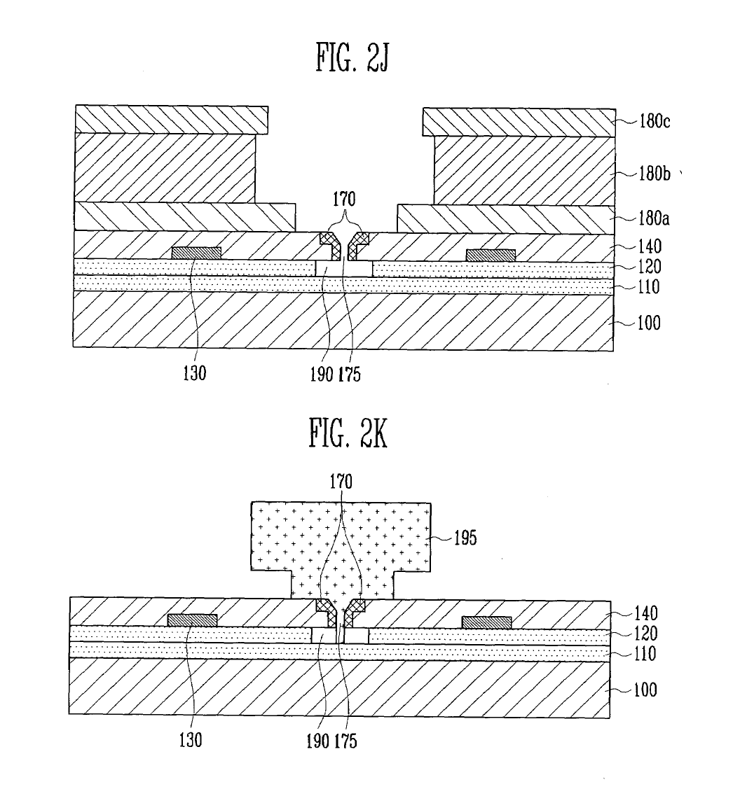

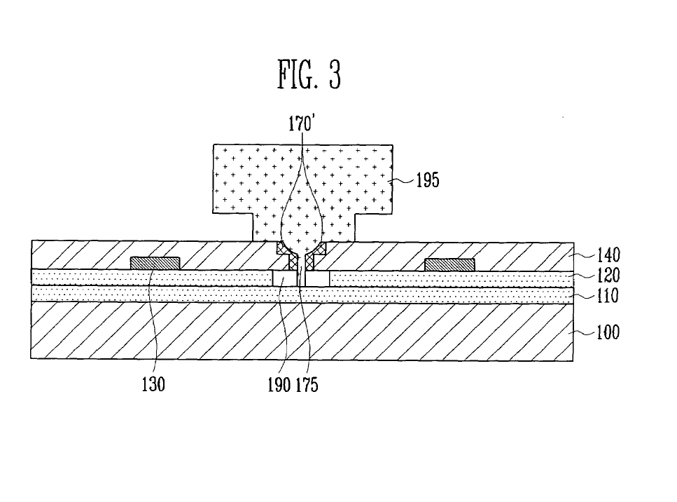

A method of forming a fine T-shaped gate electrode according to an exemplary embodiment of the present invention will now be described with reference to FIGS. 2A to 2K.

An active layer 110 and a capping layer 120 are first formed on a semiconductor substrate (in FIG. 2A), and a photoresist pattern then defines a region where an ohmic metal layer 130 which will serve as a source and a drain is to be formed. An ohmic metal is deposited, thereby forming an ohmic metal layer 130 through a process called rapid thermal annealing (RTA) (in FIG. 2B).

Here, the ohmic metal layer 130 may be a metal layer having a multi-layered structure in which AuGe, Ni and Au are deposited to a predetermined thickness.

A first insulating layer 140 with a predetermined thickness is then deposited on the capping and ohmic metal layers 120 and 130. The first insulating layer 140 may be formed of a material such as silicon nitride or silicon oxide to protect the surface of a compound semiconductor substrate. Here, the etching thickness of the photoresist layer and the height of the T-shaped gate foot may be controlled by adjusting the thickness of the first insulating layer 140 (in FIG. 2C).

A multi-layered photoresist layer with different sensitivities is coated on the substrate 100 in consideration of an etch selectivity with respect to the insulating layer, and then a fine pattern with an opening that has an upper part wider than a lower part is formed in the multi-layered photoresist layer. In this embodiment, polymethyl methacrylate (PMMA) or ZEP is used to form the lowermost photoresist layer (a first photoresist layer 150), and a material with a higher sensitivity than the first photoresist layer 150, for example, methyl methacrylate-co-methacrylic acid polymer (MMA-MAA) or polymethylglutarimide (PMGI) is used to form a layer (a second photoresist layer 160) on the first photoresist layer 150, and thus an opening defined by the second photoresist layer 160 has a larger pattern than an opening defined by the first photoresist layer 150 after development of both the photoresist layers (in FIG. 2D). The openings of the first and second photoresist layers may have a size ratio of 1:1.2 to 1:3.

If the ratio is greater than 1:3, the opening of the second photoresist layer is far larger than that of the first photoresist layer, thereby not affecting the formation of a V-shaped groove after deposition of a second insulating layer. Whereas, if it is between 1:1 and 1:1.2, the sizes of the openings of the first and second photoresist layers are similar, and thus an etch result after deposition of the second insulating layer is similar to that when the sizes of the openings thereof are equal.

Unlike the embodiment illustrated in this drawing, the size ratio of the openings of the first and second photoresist layers may also be 1:0.3 to 1:0.8, which are the reversed ratio of the openings of the first and second photoresist layers.

That is, considering an etch selectivity between the second photoresist layer and the insulating layer under the given etching condition, the thickness of the second photoresist layer is adjusted to etch the second photoresist layer during etching of the insulating layer. As a result, the lower part of the step hole may have an equal width to the opening of the second photoresist layer, and the upper part of the hole may have an equal width to the opening of the first photoresist layer. Here, the first and second photoresist layers have to be formed of materials opposite to those described above.

A dry etching process is then performed to anisotropically etch the first insulating layer 140 exposed through the photoresist pattern (in FIG. 2E). The etching process is performed using the photoresist pattern as an etch mask. In the process, the first photoresist layer 150 exposed by the wide opening of the second photoresist layer 160, and the upper part of the first insulating layer 140 under the first photoresist layer 150 are etched, and the lower part of the first insulating layer 140 is etched to the size of the opening of the first photoresist layer 150. As a result, the opening formed in the first insulating layer 140 has a step hole structure in which its upper part is wider than its lower part.

The anisotropic etching process of the insulating layer, when the first insulating layer 140 is formed of silicon nitride or silicon oxide, may be performed through a dry etching process using a gas or gaseous mixture selected from the group consisting of CF₄, a mixture of CF₄ and CHF₃, a mixture of CF₄ and O₂, and C₂H₆, for example, reactive ion etching (RIE), magnetically enhanced reactive ion etching (MERIE), or inductive coupled plasma (ICP).

The photoresist layer remaining on the semiconductor substrate 100 after the etching process of the first insulating layer 140 is removed with acetone or microwave (in FIG. 2F), and a second insulating layer 170 is deposited on the entire surface of the semiconductor substrate 100. Here, the second insulating layer 170 has a V-shaped groove 173 due to the step hole 175 in the first insulating layer 140 formed before the deposition (in FIG. 2G).

The second insulating layer 170 is then etched without an etch mask to expose the semiconductor substrate 100, and remains on walls of the step hole 175. The step hole 175 is formed by etching back the second insulating layer 170 to have an opening with a wide upper part and a narrow lower part (in FIG. 2H). Here, the thickness of the remaining second insulating layer is adjusted by the etch-back process to adjust the length of the gate foot, and the upper part of the hole is formed wider than the lower part thereof, thereby improving step coverage, which results in improved junction characteristic of a gate electrode in manufacturing a ultra-fine gate electrode below 0.1 μm.

Photoresist layers are sequentially formed to have a T- or gamma-shaped pattern having an opening exposing the hole in the first insulating layer 140. Here, an opening of a lower photoresist layer 180a is formed smaller than an opening of an upper photoresist layer 180b, and thus a T- or gamma-shaped gate head pattern whose upper part is wider than the lower part thereof is completed (in FIG. 2I). Also, in the embodiment, another photoresist layer 180c is further disposed on the photoresist layer 180b, which makes it easy to form the gate pattern, but the invention is not limited thereto. Accordingly, the photoresist layer may comprise only one layer, and in this case, the layer can form only the T- or gamma-shaped head pattern. The shape, number, or thickness of such a photoresist layer may be easily transformed by those skilled in the art, and thus the detailed descriptions thereof will be omitted.

A gate recess region 190 on which a gate metal will be deposited is formed by a gate recess process of etching the semiconductor substrate exposed on the T-shaped gate pattern (in FIG. 2J). The gate recess process 190 is a critical step in manufacturing a device using a compound semiconductor, such as a high electron mobility transistor (HEMT), a metal semiconductor field effect transistor (MESFET), etc., which is generally performed while measuring current, and in a single step or several steps comprising a wet process, a dry process, or a composition thereof. For example, the gate recess process may be performed using a gas such as BCl₃ or SF₆ in a dry etching apparatus such as electron cyclotron resonance (ECR) and ICP, or using various wet etching solutions such as a phosphoric acid-based solution in which H₃PO₄H₂O₂ and H₂O are mixed at an appropriate ratio.

Here, to remove the layer damaged by plasma on the Surface of the semiconductor exposed after the etching process of the second insulating layer 170, the gate recess process may be performed in a sequence of wet/dry/wet etching processes.

Finally, a gate metal 195 is deposited, and the photoresist layers are removed by a lift-off process. Here, in a case of an HEMT device, the gate metal 195 may be formed by sequentially depositing metal layers such as Ti, Pt, and Au.

FIG. 3 illustrates a T- or gamma gate electrode formed according to another exemplary embodiment of the present invention. The formation method of the gate electrode in this embodiment is the same as the above-described method, except for the shape of the second insulating layer which remains on the walls of the hole formed in the first insulating layer, so the detailed descriptions will be omitted.

According to the present invention, a method of forming a T- or gamma-shaped gate electrode may easily and stably form a step hole whose upper part is wider than a lower part thereof on an insulating layer using photoresist layers with different sensitivities.

Consequently, the method may easily adjust step coverage as well as the length and height of a gate foot without insulating layers with various etch rates, thereby improving junction characteristics of the gate electrode.

While the invention has been shown and described with reference to certain exemplary embodiments thereof, it will be understood by those skilled in the art that various changes in forms and details may be made therein without departing from the spirit and scope of the invention as defined by the appended claims.

What is claimed is:

1. A method of forming a T- or gamma-shaped gate electrode, comprising:
a first step of depositing a first insulating layer on a semiconductor substrate;
a second step of coating at least two photoresist layers with different sensitivities from each other on the first insulating layer, and patterning the photoresist layers to have openings which are different in size;
a third step of etching the first insulating layer using the photoresist layers as etch masks to form a step hole in which a part contacting the substrate is narrower than an upper part thereof, and removing the photoresist layers;
a fourth step of forming a photoresist layer on the first insulating layer, and forming an opening in the photoresist layer to have a T- or gamma-shaped gate head pattern;
a fifth step of performing a gate recess process with respect to the gate pattern; and
a sixth step of depositing a gate metal on the gate pattern, and removing the photoresist layers.

2. The method according to claim 1, wherein the thickness of the first insulating layer is adjusted to adjust the height of a gate foot.

3. The method according to claim 1, wherein the first insulating layer comprises at least one layer.

4. The method according to claim 1, wherein the photoresist layer coated in the second step comprises first and second photoresist layers, the first photoresist layer contacting the first insulating layer is formed of polymethyl methacrylate (PMMA) or ZEP, and the second photoresist layer contacting the first photoresist layer is formed of methyl methacrylate-co-methacrylic acid polymer (MMA-MAA) or polymethylglutarimide (PMGI).

5. The method according to claim 4, wherein the openings of the first and second photoresist layers have a size ratio of 1:1.2 to 1:3.

6. The method according to claim 4, wherein the lower part of the step hole has a width equal to the opening of the first photoresist layer, and the upper part of the step hole has a width equal to the opening of the second photoresist layer.

7. The method according to claim 1, wherein the photoresist layer coated in the second step comprises first and second photoresist layers, the first photoresist layer contacting the first insulating layer is formed of MMA-MAA or PMGI, and the second photoresist layer contacting the first photoresist layer is formed of PMMA or ZEP.

8. The method according to claim 7, wherein the openings of the first and second photoresist layers have a size ratio of 1:0.3 to 1:0.8.

9. The method according to claim 7, wherein the lower part of the step hole has a width equal to the opening of the second photoresist layer, and the upper part of the step hole has a width equal to the opening of the first photoresist layer.

10. The method according to claim 1, wherein the photoresist layer in the fourth step comprises at least one layer, and has a bar-shaped gate head pattern.

11. The method according to claim 1, wherein the photoresist layer in the fourth step comprises at least two layers, and the lower photoresist layer has an opening smaller than that of the upper photoresist layer, thereby forming a T- or gamma-shaped gate head pattern whose tipper part is wider than the lower part.

12. The method according to claim 1, further comprising the steps of:
after the third step,
depositing a second insulating layer on the first insulating layer, and etching back the second insulating layer to partially expose the semiconductor substrate and remain the second insulating layer on a wall of the step hole.
